(19) United States
(12) Patent Application Publication
(10) Pub. No.: US 2012/0056863 A1
(43) Pub. Date: Mar. 8, 2012

(54) Oscillator Circuit and Semiconductor Device Using the Oscillator Circuit

(75) Inventors: Kazunori Watanabe, Atsugi (JP); Yoshiaki Ito, Tokyo (JP)

(73) Assignee: Semiconductor Energy Laboratory Co., Ltd.

(21) Appl. No.: 13/224,548

(22) Filed: Sep. 2, 2011

(30) Foreign Application Priority Data
Sep. 3, 2010 (JP) 2010-197907

(51) Int. Cl. G09G 5/00; H03K 3/26

(52) U.S. Cl. 345/211; 331/111

(57) ABSTRACT

The oscillator circuit includes a comparator circuit which compares a potential supplied to one of input terminals with a potential supplied to the other of the input terminals and outputs a high power supply potential or a low power supply potential, a capacitor which is electrically connected to the one of the input terminals of the comparator circuit, and a charge and discharge circuit which charges and discharges the capacitor. The charge and discharge circuit includes a first current supply circuit and a second current supply circuit. Each of a current value of the first current supply circuit and a current value of the second current supply circuit can be controlled with the use of a digital control signal.

### TECHNICAL FIELD

The present invention relates to an oscillator circuit which can change a duty cycle with the use of a software program and a semiconductor device using the oscillator circuit.

### BACKGROUND ART

As an oscillator circuit which can change a duty cycle, a circuit using three or more comparator circuits (also referred to as comparators, amplifier circuits, amplifiers, or operational amplifiers) is proposed (e.g., Patent Document 1). In Patent Document 1, FIG. 5 illustrates a PWM generation circuit which can change a duty cycle and which includes a triangle wave oscillator and a comparator circuit (a comparator), and FIG. 1 illustrates a triangle wave oscillator which includes two comparator circuits (amplifiers). That is to say, Patent Document 1 shows a PWM generation circuit which includes three comparator circuits (comparators or amplifiers). However, the circuit includes three or more comparator circuits; therefore, in the case of integration, high power consumption and a large layout area are problems.

In addition, as an oscillator circuit which can change a duty cycle, a circuit including a variable resistor (e.g., Patent Document 2). In Patent Document 2, FIG. 5 illustrates the use of a variable resistor for controlling a value of current for charging and discharging a capacitor. However, a resistor of an integrated circuit has problems such as a large layout area, large variation, bias dependence, temperature dependence, and the like. Further, it is difficult to make a variable resistor in an integrated circuit.

### REFERENCE

[Patent Document 1] Japanese Unexamined Utility Model Application Publication S61-035438
[Patent Document 2] Japanese Published Patent Application No. H4-168803

### DISCLOSURE OF INVENTION

An object is to provide a novel oscillator circuit which can change a duty cycle and a semiconductor device including the novel oscillator circuit. An object is to reduce power consumption of an oscillator circuit. An object is to reduce a layout area of an oscillator circuit. An object is to change a duty cycle of an oscillator circuit with the use of a software program.

An embodiment of the present invention is an oscillator circuit and a semiconductor device including the oscillator circuit. The oscillator circuit includes a comparator circuit configured to compare a potential supplied to one of input terminals with a potential supplied to the other of the input terminals and to output a high power supply potential or a low power supply potential, a capacitor electrically connected to the one of the input terminals of the comparator circuit, a charge and discharge circuit charging and discharging the capacitor. The charge and discharge circuit includes a first current supply circuit and a second current supply circuit. A current value of the first current supply circuit and a current value of the second current supply circuit can be controlled with the use of a digital control signal.

In the oscillator circuit, a duty cycle is determined in accordance with a ratio of a current value of a first current supply circuit to a current value of a second current supply circuit. Accordingly, current values are controlled with the use of a digital control signal, whereby a duty cycle of an oscillator circuit can be accurately controlled. Further, an oscillator circuit can be combined easily with another digital circuit, and further, a duty cycle can be controlled by a software program because the oscillator circuit can be controlled digitally.

The oscillator circuit can include a wiring which supplies a reference potential and is electrically connected to the other of the input terminals of the comparator circuit.

The oscillator circuit can have a configuration in which a potential supplied to the other of the input terminals of the comparator circuit can be set at any one of two different potentials in accordance with an output potential of the comparator circuit.

The oscillator circuit can include a first resistor provided between an output terminal of the comparator circuit and the other of the input terminals of the comparator circuit and a second resistor provided between the other of the input terminals of the comparator circuit and a wiring supplying the reference potential, as a means for generating a potential supplied to the other of the input terminals of the comparator circuit.

The charge and discharge circuit can include a switching circuit whose connection state is controlled in accordance with the output potential of the comparator circuit. The switching circuit is provided between the first current supply circuit and the capacitor and between the second current supply circuit and the capacitor. The switching circuit has a function of electrically connecting the capacitor to any one of the first current supply circuit and the second current supply circuit in accordance with the output potential of the comparator circuit.

When the output potential of the comparator circuit becomes the high power supply potential, the first current supply circuit and the capacitor are electrically connected by the switching circuit. When the output potential of the comparator circuit becomes the low power supply potential, the second current supply circuit and the capacitor are electrically connected by the switching circuit.

The switching circuit includes a first switch provided between the first current supply circuit and the capacitor and a second switch provided between the second current supply circuit and the capacitor. Connection states of the first switch and the second switch can be controlled in accordance with the output potential of the comparator circuit.

In the case where the switching circuit includes the first switch and the second switch, when the output potential of the comparator circuit becomes the high power supply potential, the first switch is turned on, whereby the first current supply circuit and the capacitor are electrically connected and the second switch is turned off, whereby the second current supply circuit and the capacitor are electrically disconnected. When the output potential of the comparator circuit becomes the low power supply potential, the second switch is turned off, whereby the second current supply circuit and the capacitor are electrically connected and the first switch is turned off, whereby the first current supply circuit and the capacitor are electrically disconnected.

The switching circuit may include a signal generation circuit that generates a signal controlling the connection states of the first switch and the second switch in accordance with the output potential of the comparator circuit.

The first current supply circuit included in the oscillator circuit has a function of charging the capacitor and the second current supply circuit included in the oscillator circuit has a function of discharging the capacitor.

One of electrodes of the capacitor included in the oscillator circuit is electrically connected to the one of the input terminals of the comparator circuit, and the other of the electrodes of the capacitor is electrically connected to a wiring supplying any fixed potential.

A period for charging the capacitor by the first current supply circuit can be determined in accordance with the current value of the first current supply circuit, a capacitance value of the capacitor, and a potential of the other of the input terminals of the comparator circuit; and a period for discharging the capacitor by the second current supply circuit can be determined in accordance with the current value of the second current supply circuit, the capacitance value of the capacitor, and a potential of the other of the input terminals of the comparator circuit.

In an oscillator circuit according to an embodiment of the present invention and a semiconductor device using the oscillator circuit, the duty cycles can be accurately controlled digitally. An oscillator circuit can be combined easily with another digital circuit, and further, a duty cycle can be controlled by a software program because the oscillator circuit can be controlled digitally. The number of comparator circuits to be used can be one, and therefore, power consumption of an oscillator circuit can be reduced. The number of comparator circuits to be used can be one and a variable resistor is not used, and therefore, the circuit can be integrated and a layout area can be reduced.

### BRIEF DESCRIPTION OF DRAWINGS

FIG. 1 illustrates an example of a configuration of an oscillator circuit.

FIGS. 2A and 2B each illustrate an example of operation of the oscillator circuit.

FIGS. 3A and 3B each illustrate an example of a timing diagram of the oscillator circuit.

FIGS. 4A and 4B each illustrate an example of a current supply circuit included in an oscillator circuit.

FIG. 5 illustrates an example of a comparator circuit included in an oscillator circuit.

FIG. 6 illustrates an example of a configuration of the oscillator circuit.

FIG. 7 illustrates an example of a current supply circuit included in an oscillator circuit.

FIGS. 8A and 8B each illustrate a graph of a calculation result of the operation of an oscillator circuit.

### BEST MODE FOR CARRYING OUT THE INVENTION

Hereinafter, embodiments will be described in detail with reference to the accompanying drawings. However, since embodiments described below can be embodied in many different modes, it is easily understood by those skilled in the art that the mode and the detail can be variously changed without departing from the scope of the present invention. Accordingly, the embodiments of the present invention should not be construed as being limited to the following description. In the drawings for explaining the embodiments, the same parts or parts having a similar function are denoted by the same reference numerals, and description of such parts is not repeated.

In the case of using a transistor in the following embodiments, a transistor in which a channel formation region provided between a source and drain is a wide gap semiconductor such as an oxide semiconductor or a transistor in which the channel formation region is a semiconductor such as silicon or germanium which is amorphous, microcrystalline, polycrystalline, or single crystalline may be used, for example.

### Embodiment 1

In this embodiment, an example of the configuration and the operation of an oscillator circuit will be described.

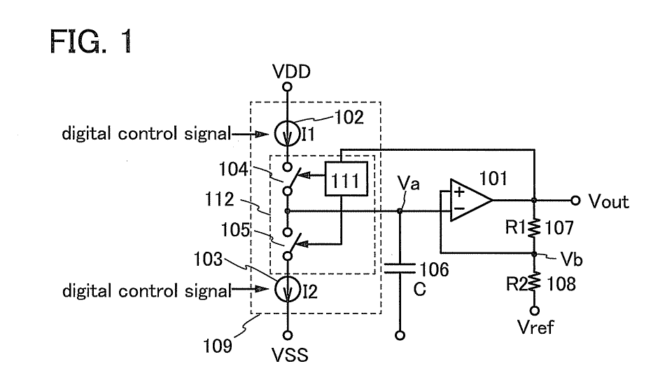

FIG. 1 illustrates an example of a circuit diagram of an oscillator circuit. The oscillator circuit includes a comparator circuit 101, a capacitor 106, and a charge and discharge circuit 109. The comparator circuit 101 compares a potential Va supplied to one of input terminals (also referred to as a minus input terminal or an inverting input terminal) with a potential Vb supplied to the other of the input terminals (also referred to as a plus input terminal or a non-inverting input terminal), and outputs a high power supply potential (VDD) or a low power supply potential (VSS). When the potential Vb of the other of the input terminals is larger, an output potential is the high power supply potential (VDD). When the potential Va of the one of the input terminals is larger, the output potential is the low power supply potential (VSS).

The charge and discharge circuit 109 charges and discharges the capacitor 106. The capacitor 106 is electrically connected to the one of the input terminals of the comparator circuit 101. Accordingly, the potential Va of the one of the input terminals of the comparator circuit 101 is determined in accordance with electric charge accumulated in the capacitor 106.

The charge and discharge circuit 109 includes a current supply circuit 102, a current supply circuit 103, and a switching circuit 112. A current value I1 of the current supply circuit 102 and the current value I2 of the current supply circuit 103 can be controlled with the use of a digital control signal. A duty cycle D of the oscillator circuit can be determined in accordance with a ratio of the current value I1 of the current supply circuit 102 to the current value I2 of the current supply circuit 103.

The current supply circuit 102 has a function of charging the capacitor 106 and the current supply circuit 103 has a function of discharging the capacitor 106.

One of electrodes the capacitor 106 is electrically connected to the one of the input terminals of the comparator circuit 101, and the other of the electrodes of the capacitor 106 is electrically connected to a wiring supplying any fixed potential. Accordingly, the potential of the one of the electrodes of the capacitor 106 is equal to the potential Va of the one of the input terminals of the comparator circuit 101.

The switching circuit 112 is provided between the current supply circuit 102 and the capacitor 106 and between the current supply circuit 103 and the capacitor 106. The switching circuit 112 electrically connects any one of the current supply circuit 102 and the current supply circuit 103 to the capacitor 106 in accordance with the output potential of the comparator circuit 101.

For example, when the output potential of the comparator circuit 101 becomes the high power supply potential (VDD), the current supply circuit 102 and the capacitor 106 are electrically connected to each other by the switching circuit 112. When the output potential of the comparator circuit 101 becomes the low power supply potential (VSS), the current supply circuit 103 and the capacitor 106 are electrically connected to each other by the switching circuit 112.

For example, the switching circuit 112 can include a switch 104 provided between the current supply circuit 102 and the capacitor 106 and a switch 105 provided between the current supply circuit 103 and the capacitor 106. The connection state of the switch 104 and the connection state of the switch 105 are controlled in accordance with an output potential Vout of the comparator circuit 101.

One of the switch 104 and the switch 105 is turned on in accordance with the output potential Vout of the comparator circuit 101, so that one of the current supply circuit 102 and the current supply circuit 103 are electrically connected to the capacitor 106. When the switch 104 is turned on, and the current supply circuit 102 and the capacitor 106 are electrically connected, the capacitor 106 is charged. When the switch 105 is turned on, and the current supply circuit 103 and the capacitor 106 are electrically connected, the capacitor 106 is discharged.

Further, the switching circuit 112 may include a signal generation circuit 111 configured to generate a signal that controls the connection states of the switch 104 and the switch 105 in accordance with the output potential of the comparator circuit 101.

The other of the input terminals of the comparator circuit 101 is electrically connected to a wiring supplying a reference potential Vref The reference potential Vref can have a constant value between the high power supply potential (VDD) and the low power supply potential (VSS). Note that a configuration using one reference potential is shown here, but a configuration using two reference potentials may be employed.

As a means for generating a potential supplied to the other of the input terminals of the comparator circuit 101, a resistor 107 is provided between an output terminal of the comparator circuit 101 and the other of the input terminals of the comparator circuit 101. In addition, a resistor 108 is provided between the other of the input terminals of the comparator circuit 101 and a wiring supplying the reference potential Vref The potential Vb supplied to the other of the input terminals of the comparator circuit 101 is determined by the reference potential Vref, a resistance value R1 of the resistor 107, a resistance value R2 of the resistor 108, and the output potential Vout.

When the potential Vb which is supplied to the other of the input terminals in the case where the output potential Vout of the comparator circuit 101 is the high power supply potential (VDD) is Vb1, the potential Vb1 is expressed by Formula 1.

$$Vb 1 = Vref + ( VDD - Vref ) \times \frac{R 2}{R 1 + R 2} \qquad [ FORMULA 1 ]$$

When the potential Vb which is supplied to the other of the input terminal in the case where the output potential Vout of the comparator circuit 101 is the low power supply potential (VSS) is Vb2, the potential Vb2 is expressed by Formula 2.

$$Vb 2 = Vref + ( VSS - Vref ) \times \frac{R 2}{R 1 + R 2} \qquad [ FORMULA 2 ]$$

Note that in the above description, the potential Vb supplied to the other of the input terminals of the comparator circuit 101 is set at any one of the potential Vb1 and the potential Vb2 with the use of the resistor 107 and the resistor 108; however, an oscillator circuit according to this embodiment is not limited to this configuration. It is only necessary that the value of the potential Vb which is supplied to the other of the input terminals of the comparator circuit 101 in accordance with the output potential Vout of the comparator circuit 101 can be set at any one of two different potentials such as the potential Vb1 and the potential Vb2. For example, without using the resistor 107 and the resistor 108, the potential Vb can be set at any one of potentials by using a switch and two different reference potentials.

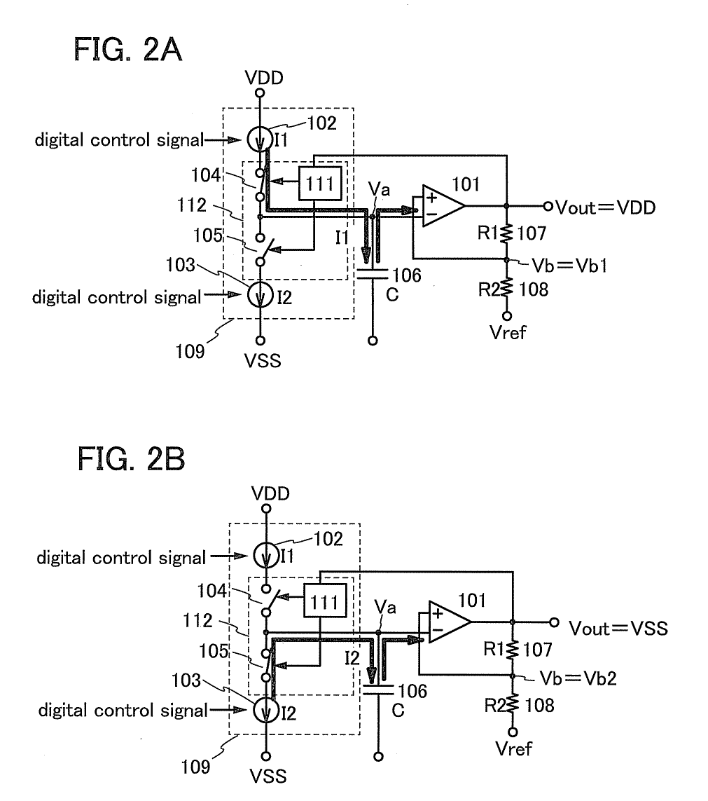

Next, the operation of the oscillator circuit will be described with reference to FIGS. 2A and 2B. First, the case where the output potential Vout of the comparator circuit 101 is changed from the low power supply potential (VSS) to the high power supply potential (VDD) will be described with reference to FIG. 2A.

When the output potential Vout of the comparator circuit 101 becomes the high power supply potential (VDD), the switch 104 is turned on, and the current supply circuit 102 and the capacitor 106 are electrically connected to each other; thus, the capacitor 106 is charged. At that time, the switch 105 is in an off state.

At the start of charging the capacitor 106, the potential Va of the one of the electrodes of the capacitor 106 is slightly lower than the potential Vb2. At the start of charging the capacitor 106, the potential Vb of the other of the input terminals of the comparator circuit 101 is the potential Vb1.

The capacitor 106 is charged with the use of the current supply circuit 102 with the current value I1 until the potential Va of the one of the electrodes of the capacitor 106 becomes slightly higher than the potential Vb1 of the other of the input terminals of the comparator circuit 101. Note that the potential Vb1 of the other of the input terminals of the comparator circuit 101 is kept at the potential Vb1 during the charge of the capacitor 106.

When the potential Va of the one of the electrodes of the capacitor 106 becomes slightly higher than the potential Vb1 of the other of the input terminals of the comparator circuit 101, the output potential Vout of the comparator circuit 101 is changed from the high power supply potential (VDD) to the low power supply potential (VSS).

Note that a charging period T1 of the capacitor 106 is determined in accordance with the current value I1 of the current supply circuit 102, a capacitance value C of the capacitor 106, and the potential Vb of the other of the input terminals of the comparator circuit 101. Specifically, the charging period T1 is expressed by Formula 3.

$$T 1 = \frac{C \times ( Vb 1 - Vb 2 )}{I 1} \qquad [ FORMULA 3 ]$$

Next, the case where the output potential Vout of the comparator circuit 101 is changed from the high power supply potential (VDD) to the low power supply potential (VSS) will be described with reference to FIG. 2B.

When the output potential Vout of the comparator circuit 101 becomes the low power supply potential (VSS), the switch 105 is turned on, and the current supply circuit 103 and the capacitor 106 are electrically connected to each other; thus, the capacitor 106 is discharged. At that time, the switch 104 is in an off state.

At the start of discharging the capacitor 106, the potential Va of the one of the electrodes of the capacitor 106 is slightly higher than the potential Vb1. At the start of discharging the capacitor 106, the potential Vb of the other of the input terminals of the comparator circuit 101 is the potential Vb2.

The capacitor 106 is discharged with the use of the current supply circuit 103 with the current value I2 until the potential Va of the one of the electrodes of the capacitor 106 becomes slightly lower than the potential Vb2 of the other of the input terminals of the comparator circuit 101. Note that the potential Vb2 of the other of the input terminals of the comparator circuit 101 is kept at the potential Vb2 during the discharge of the capacitor 106.

When the potential Va of the one of the electrodes of the capacitor 106 becomes slightly lower than the potential Vb2 of the other of the input terminals of the comparator circuit 101, the output potential Vout of the comparator circuit 101 is changed from the low power supply potential (VSS) to the high power supply potential (VDD).

Note that a discharging period T2 of the capacitor 106 is determined in accordance with the current value I2 of the current supply circuit 103, a capacitance value C of the capacitor 106, and the potential Vb of the other of the input terminals of the comparator circuit 101. Specifically, the discharging period T2 is expressed by Formula 4.

$$T 2 = \frac{C \times ( Vb 1 - Vb 2 )}{I 2} \qquad [ FORMULA 4 ]$$

After that, oscillation is maintained by repetition of the above operation.

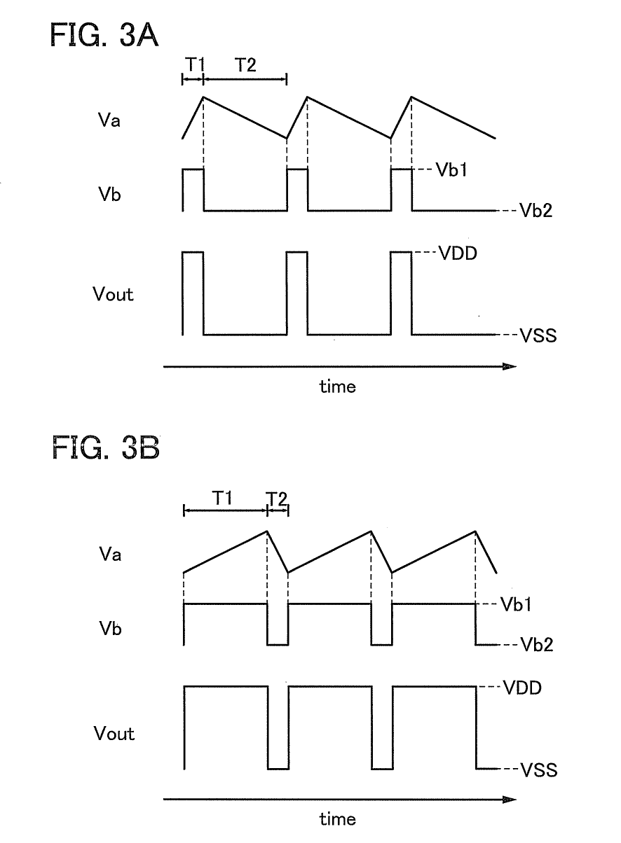

FIGS. 3A and 3B are examples of a timing diagram of the oscillator circuit. FIGS. 3A and 3B are timing diagrams of the potential Va of the one of the input terminals of the comparator circuit 101, the potential Vb of the other of the input terminals of the comparator circuit 101, and the output potential Vout of the comparator circuit 101. Note that the output potential of the oscillator circuit is equal to the output potential Vout of the comparator circuit 101.

First, the charging period T1 will be described. As described above, in the charging period T1, the potential Va at the start of charging the capacitor 106 is slightly lower than the potential Vb2. The potential Vb in the charging period T1 is the potential Vb1. The capacitor 106 is charged with the use of the current supply circuit 102 with the current value I1 until the potential Va is slightly higher than the potential Vb1.

When the potential Va becomes slightly higher than the potential Vb1, the output potential Vout of the comparator circuit 101 is changed from the high power supply potential (VDD) to the low power supply potential (VSS); thus, the charging period T1 is finished.

As shown by Formula 3, the charging period T1 is determined in accordance with the current value I1 of the current supply circuit 102, the capacitance value C of the capacitor 106, and the potential Vb of the other of the input terminals of the comparator circuit 101. In operation, the charging period T1 can be determined by control of the current value I1 of the current supply circuit 102. The charging period T1 can be short when the current value I1 of the current supply circuit 102 is large. The charging period T1 can be long when the current value I1 of the current supply circuit 102 is small.

First, the discharging period T2 will be described. As described above, in the discharging period T2, the potential Va at the start of discharging the capacitor 106 is slightly higher than the potential Vb1. The potential Vb in the discharging period T2 is the potential Vb2. The capacitor 106 is discharged with the use of the current supply circuit 103 with the current value I2 until the potential Va is slightly lower than the potential Vb2.

When the potential Va becomes slightly lower than the potential Vb2, the output potential Vout of the comparator circuit 101 is changed from the low power supply potential (VSS) to the high power supply potential (VDD); thus, the discharging period T2 is finished.

As shown by Formula 4, the discharging period T2 is determined in accordance with the current value I2 of the current supply circuit 103, the capacitance value C of the capacitor 106, and the potential Vb of the other of the input terminals of the comparator circuit 101. In operation, the discharging period T2 can be determined by control of the current value I2 of the current supply circuit 103. The discharging period T2 can be short when the current value I2 of the current supply circuit 103 is large. The discharging period T2 can be long when the current value I2 of the current supply circuit 103 is small.

As described above, by control of the current value I1 of the current supply circuit 102 and the current value I2 of the current supply circuit 103, the lengths of the charging period T1 and the discharging period T2 can be controlled and the duty cycle D of the oscillator circuit can be changed. That is to say, the duty cycle D of the oscillator circuit can be determined in accordance with a ratio of the current value I1 of the current supply circuit 102 to the current value I2 of the current supply circuit 103. Note that the duty cycle D of the oscillator circuit is expressed as follows, using a period in which the output potential Vout is the high power supply potential (VDD) and a period in which the output potential Vout is the low power supply potential (VSS), that is, the charging period T1 and the discharging period T2: D=T1/(T1+T2). When Formula 3 and Formula 4 are substituted into T1 and T2, respectively, the duty cycle D is expressed by Formula 5.

$$D = \frac{T 1}{T 1 + T 2} = \frac{1 / I 1}{( 1 / I 1 + 1 / I 2 )} = \frac{1}{1 + I 1 / I 2} \qquad [ FORMULA 5 ]$$

FIG. 3A shows the case where the charging period T1 of the capacitor 106 is shorter than the discharging period T2 of the capacitor 106. In FIG. 3A, the duty cycle D of the oscillator circuit is less than 50% (e.g., about 20%).

In FIG. 3A, the current value I1 of the current supply circuit 102 is set to be larger than the current value I2 of the current supply circuit 103. Note that the current value I1 of the current supply circuit 102 and the current value I2 of the current supply circuit 103 are each determined with the use of a digital control signal. Accordingly, a current value is controlled with the use of a digital control signal, whereby the duty cycle of an oscillator circuit can be accurately controlled. The oscillator circuit can be combined easily with another digital circuit, and further, the duty cycle can be controlled by a software program because the oscillator circuit can be controlled digitally.

FIG. 3B shows the case where the discharging period T2 of the capacitor 106 is shorter than the charging period T1 of the capacitor 106. In FIG. 3B, the duty cycle D of the oscillator circuit is greater than 50% (e.g., about 80%).

In FIG. 3B, the current value I2 of the current supply circuit 103 is set to be larger than the current value I1 of the current supply circuit 102. Note that the current value I1 of the current supply circuit 102 and the current value I2 of the current supply circuit 103 are each determined with the use of a digital control signal. Accordingly, a current value is controlled with the use of a digital control signal, whereby the duty cycle of an oscillator circuit can be accurately controlled. The oscillator circuit can be combined easily with another digital circuit, and further, the duty cycle can be controlled by a software program because the oscillator circuit can be controlled digitally.

The oscillator circuit described in this embodiment can be used for various semiconductor devices. For example, in an electronic device using a semiconductor device including a display portion, the oscillator circuit described in this embodiment can be used for part of a driver circuit portion that drives the display portion. In the case of a portable electronic device using a semiconductor device, it is very advantageous to use the oscillator circuit described in this embodiment, in which case, the usability of the portable electronic device can be dramatically improved by reduction in weight, size, and power consumption.

In the oscillator circuit according to this embodiment and a semiconductor device using the oscillator circuit, the duty cycles can be accurately controlled digitally. The oscillator circuit can be combined easily with another digital circuit, and further, the duty cycle can be controlled by a software program because the oscillator circuit can be controlled digitally. The number of comparator circuits 101 to be used can be one, and therefore, power consumption of the oscillator circuit can be reduced. The number of comparator circuits 101 to be used can be one and a variable resistor is not used, and therefore, the circuit can be integrated and a layout area can be reduced.

This embodiment can be combined with any of the other embodiments and examples as appropriate.

### Embodiment 2

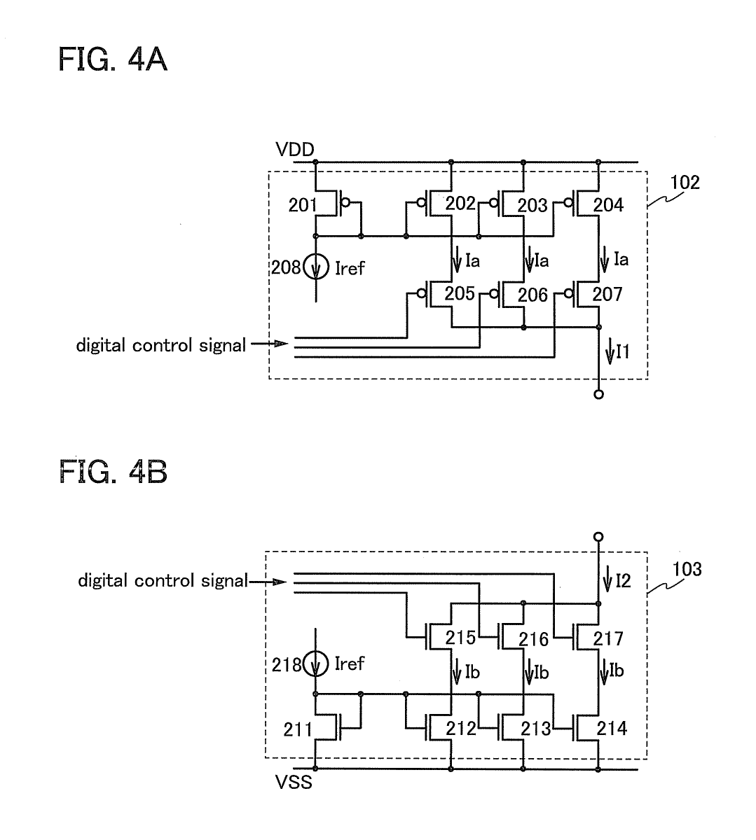

In this embodiment, examples of the configurations and operations of the current supply circuit 102 and the current supply circuit 103 that are used in the oscillator circuit in FIG. 1 will be described with reference to FIGS. 4A and 4B.

FIG. 4A illustrates a circuit diagram of the current supply circuit 102. The current supply circuit 102 has a function of charging a capacitor. The current supply circuit 102 uses a current mirror circuit, and includes transistors 201 to 207 and the current supply 208. The transistors 201 to 207 are p-channel transistors. Sources of the transistors 201 to 204 are electrically connected to the high power supply potential (VDD). A drain of the transistor 201 is electrically connected to the current supply 208 that supplies a current value Iref.

When the size of the transistor 201 is equal to the sizes of the transistors 202 to 204, the current value Iref of the drain of the transistor 201 is equal to current values Ia of drains of the transistors 202 to 204. Accordingly, the drains of two of the transistors 202 to 204 are electrically connected to each other, whereby a current value of the current supply circuit 102 can be (2×Ia). Further, the drains of the transistors 202 to 204 are electrically connected to one another, whereby a current value of the current supply circuit 102 can be (3×Ia).

The transistors 205 to 207 can be used as switches and the connection state is controlled with the use of a digital control signal. Accordingly, the transistors 205 to 207 are controlled with the use of a digital control signal, so that any one, two, or three of the transistors 202 to 204 can be on.

Note that in FIG. 4A, three current values (Ia) which are equal to each other are made with the use of the transistors 202 to 204. However, the number of current values is not limited to three as long as the configuration has a plurality of transistors that have a similar function to the transistors 202 to 204 and makes a plurality of same current values.

In addition, the sizes (e.g., the channel length and the channel width) of the transistors 202 to 204 are made to be different from the size of the transistor 201, whereby the current values of the drains of the transistors 202 to 204 can be different. For example, in the case where the channel lengths of the transistors 201 to 204 and the ratio between the channel width W1 of the transistor 201, the channel width W2 of the transistor 202, the channel width W3 of the transistor 203, and the channel width W4 of the transistor 204 is made to be 1:2:3:4, current values of the drains of the transistors 202 to 204 can be 2×Iref; 3×Iref, and 4×Iref, respectively.

In this manner, as the current value I1 of the current supply circuit 102, a plurality of current values (at most eight current values in the case of the current supply circuit 102 in FIG. 4A) can be used in accordance with a digital control signal.

FIG. 4B illustrates a circuit diagram of the current supply circuit 103. The current supply circuit 103 has a function of discharging a capacitor. The current supply circuit 103 uses a current minor circuit, and includes transistors 211 to 217 and the current supply 218. The transistors 211 to 217 are n-channel transistors. Sources of the transistors 211 to 214 are electrically connected to the low power supply potential (VSS). A drain of the transistor 211 is electrically connected to the current supply 218 that supplies a current value Iref.

When the size of the transistor 211 is equal to the sizes of the transistors 212 to 214, the current value Iref of the drain of the transistor 211 is equal to current values Ib of drains of the transistors 212 to 214. Accordingly, the drains of two of the transistors 212 to 214 are electrically connected to each other, whereby a current value of the current supply circuit 103 can be (2×Ib). Further, the drains of the transistors 212 to 214 are electrically connected to one another, whereby a current value of the current supply circuit 103 can be (3×Ib).

The transistors 215 to 217 can be used as switches and the connection state is controlled with the use of a digital control signal. Accordingly, the transistors 215 to 217 are controlled with the use of a digital control signal, so that any one, two, or three of the transistors 212 to 214 can be on.

Note that in FIG. 4B, three current values (Ib) which are equal to each other are made with the use of the transistors 212 to 214. However, the number of current values is not limited to three as long as the configuration has a plurality of transistors that have a similar function to the transistors 212 to 214 and makes a plurality of same current values.

In addition, the sizes (e.g., the channel length and the channel width) of the transistors 212 to 214 are made to be different from the size of the transistor 211, whereby the current values of the drains of the transistors 212 to 214 can be different. For example, in the case where the channel lengths of the transistors 211 to 214 and the ratio between the channel width W1 of the transistor 211, the channel width W2 of the transistor 212, the channel width W3 of the transistor 213, and the channel width W4 of the transistor 214 is made to be 1:2:3:4, current values of the drains of the transistors 212 to 214 can be 2×Iref, 3×Iref; and 4×Iref, respectively.

In this manner, as the current value I2 of the current supply circuit 103, a plurality of current values (at most eight current values in the case of the current supply circuit 103 in FIG. 4B) can be used in accordance with a digital control signal.

In the current supply circuit 102 and the current supply circuit 103 in this embodiment, a plurality of current values can be set in accordance with a digital control signal. Accordingly, the current supply circuit 102 and the current supply circuit 103 in this embodiment are used for the oscillator circuit in FIG. 1, whereby the duty cycle of the oscillator circuit can be accurately controlled. The oscillator circuit can be combined easily with another digital circuit, and further, the duty cycle can be controlled by a software program because the oscillator circuit can be controlled digitally. The number of comparator circuits to be used can be one, and therefore, power consumption of the oscillator circuit can be reduced. The number of comparator circuits to be used can be one and a variable resistor is not used, and therefore, the circuit can be integrated and a layout area can be reduced.

### Embodiment 3

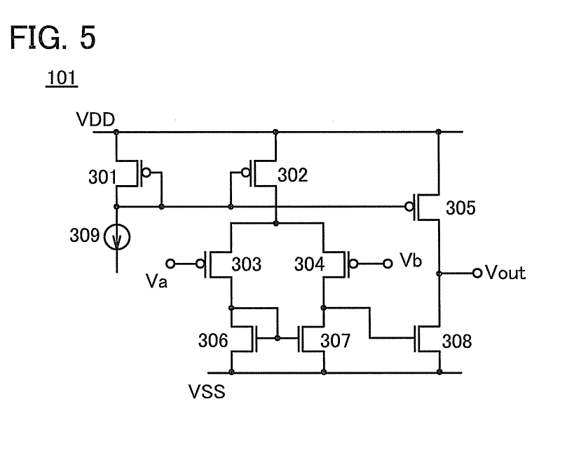

In this embodiment, an example of a configuration of the comparator circuit 101 used for the oscillator circuit in FIG. 1 will be described with reference to FIG. 5.

FIG. 5 illustrates a circuit diagram of the comparator circuit 101. The comparator circuit 101 includes transistors 301 to 308 and a current supply 309.

The comparator circuit 101 in this embodiment is used for the oscillator circuit in FIG. 1, whereby the operation described in Embodiment 1 can be performed and the duty cycle of the oscillator circuit can be accurately controlled with the use of a digital control signal. The oscillator circuit can be combined easily with another digital circuit, and further, the duty cycle can be controlled by a software program because the oscillator circuit can be controlled digitally. The number of comparator circuits to be used can be one, and therefore, power consumption of the oscillator circuit can be reduced. The number of comparator circuits to be used can be one and a variable resistor is not used, and therefore, the circuit can be integrated and a layout area can be reduced.

### Embodiment 4

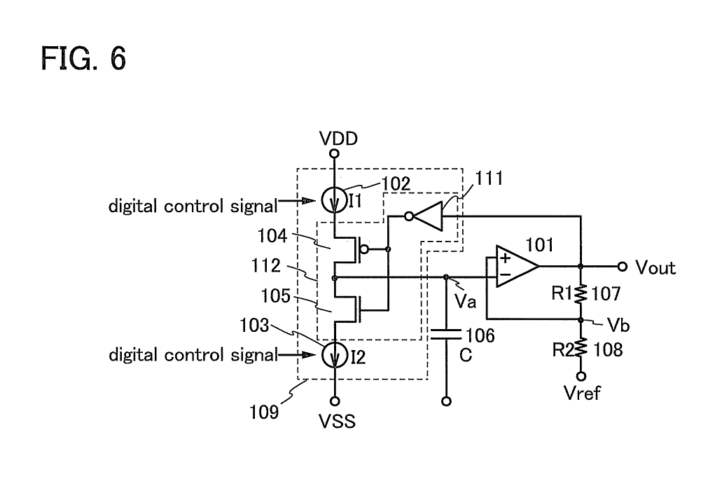

In this embodiment, an example of a configuration of the oscillator circuit in FIG. 1 will be described with reference to FIG. 6.

FIG. 6 illustrates an example of a configuration of the oscillator circuit in FIG. 1: a p-channel transistor is used as the switch 104, an n-channel transistor is used as the switch 105, and an inverter is used as the signal generation circuit 111. An input terminal of the inverter which is the signal generation circuit 111 is electrically connected to the output terminal of the comparator circuit 101. An output terminal of the inverter which is the signal generation circuit 111 is electrically connected to a gate of the p-channel transistor which is the switch 104 and a gate of the n-channel transistor which is the switch 105.

The oscillator circuit in FIG. 6 is used, whereby the operation described in Embodiment 1 can be performed and the duty cycle of an oscillator circuit can be accurately controlled with the use of a digital control signal. The oscillator circuit can be combined easily with another digital circuit, and further, the duty cycle can be controlled by a software program because the oscillator circuit can be controlled digitally. The number of comparator circuits to be used can be one, and therefore, power consumption of the oscillator circuit can be reduced. The number of comparator circuits to be used can be one and a variable resistor is not used, and therefore, the circuit can be integrated and a layout area can be reduced.

### Embodiment 5

In this embodiment, verification was performed by calculation in order to confirm operation of the oscillator circuit in FIG. 6.

Table 1 shows the following values assumed in the calculation: the high power supply potential VDD, the low power supply potential VSS, the reference potential Vref; the resistance value R1 of the resistor 107, the resistance value R2 of the resistor 108, and the capacitance value C of the capacitor 106.

TABLE 1

| | |
|---|---|
| VDD [V] | 3 |
| VSS [V] | 0 |
| Vref [V] | 1.5 |
| R1 [kΩ] | 500 |
| R2 [kΩ] | 500 |
| C [pF] | 5 |

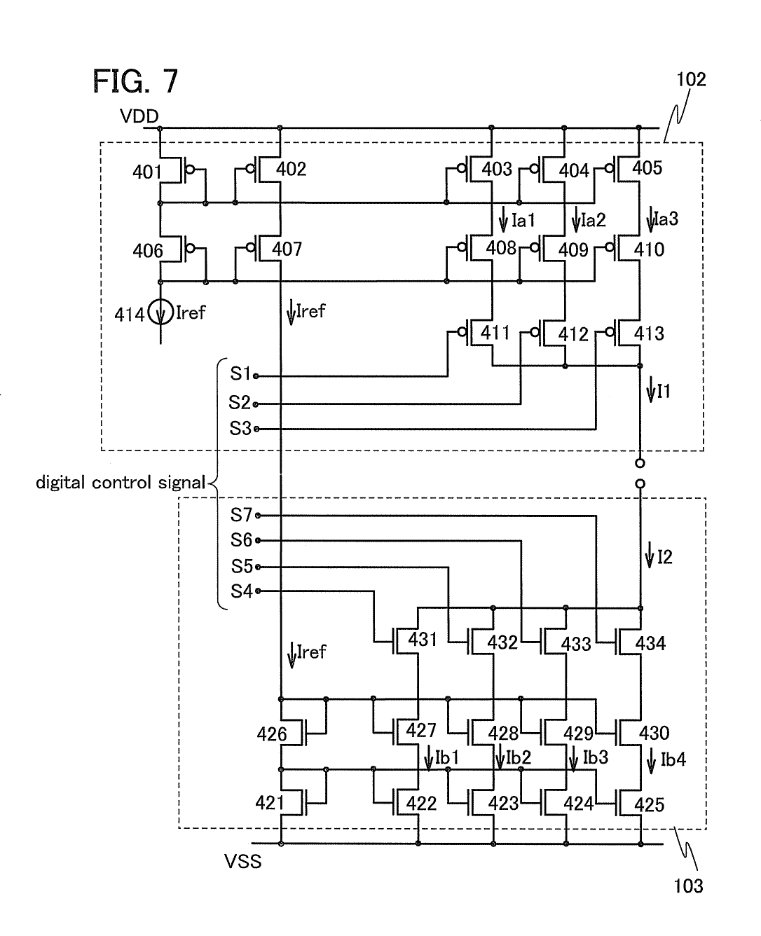

FIG. 7 illustrates a circuit diagram of the current supply circuit 102 and the current supply circuit 103 which were used for the calculation.

The circuit diagram in FIG. 7 has a configuration in which the current supply circuit 102 and the current supply circuit 103 are electrically connected to each other, and includes transistors 401 to 413, a current source 414, and transistors 421 to 434. The transistors 401 to 413 are p-channel transistors and the transistors 421 to 434 are n-channel transistors. Note that the transistors 406 to 410 and the transistors 426 to 430 are transistors connected in cascode for improving current mirroring accuracy of a current mirror circuit. The circuits in FIG. 7 have a function of generating current with the current value I1 from the current supply circuit 102 and current with the current value I2 from the current supply circuit 103 with the use of the current source 414.

The sizes (e.g., the channel length and the channel width) of the transistors 403 to 405 are made to be different from the size of the transistor 401, whereby current values (Ia1, Ia2, and Ia3) of drains of the transistors 403 to 405 can be set at a value different from the current value Iref of a drain of the transistor 401.

The sizes (e.g., the channel length and the channel width) of the transistors 422 to 425 are made to be different from the size of the transistor 421, whereby current values (Ib1, Ib2, Ib3, and Ib4) of drains of the transistors 422 to 425 can be set at a value different from the current value Iref of a drain of the transistor 421.

Table 2 shows the following values assumed in the calculation: the current value Iref, the current values Ia1 to Ia3, the current values Ib1 to Ib4.

TABLE 2

| | |
|---|---|
| Iref [μA] | 0.5 |
| Ia1 [μA] | 0.5 |
| Ia2 [μA] | 0.75 |
| Ia3 [μA] | 1.25 |
| Ib1 [μA] | 0.125 |
| Ib2 [μA] | 0.1528 |
| Ib3 [μA] | 0.1875 |
| Ib4 [μA] | 0.375 |

The transistors 411 to 413 and the transistors 431 to 434 can be used as switches and the connection state is controlled by digital control signals S1 to S7. Accordingly, by the digital control signals S1 to S7, a transistor to be on can be determined among the transistors 411 to 413 and the transistors 431 to 434.

The duty cycle D can be changed in accordance with signals (an H signal or an L signal) input as the digital control signals S1 to S7. Table 3 shows the examples (1) to (4) of signals (an H signal or an L signal) input as the digital control signals S1 to S7. Further, each of (1) to (4) shows the current value I1 of the current supply circuit 103, the current value I2 of the current supply circuit 103, the charging period T1, the discharging period T2, and the duty cycle D, which were calculated. Note that among the values in Table 3, S1 to S7 are setting values and I1 to D are designed values.

TABLE 3

| | S1 | S2 | S3 | S4 | S5 | S6 | S7 | I1 [μA] | I2 [μA] | T1 [μs] | T2[μs] | D [%] |
|---|---|---|---|---|---|---|---|---|---|---|---|---|
| (1) | L | H | H | H | L | L | H | 0.5 | 0.5 | 15 | 15 | 50 |
| (2) | H | L | H | L | L | L | H | 0.75 | 0.375 | 10 | 20 | 33 |
| (3) | H | H | L | H | L | H | L | 1.25 | 0.3125 | 6 | 24 | 20 |
| (4) | L | L | L | H | H | L | L | 2.5 | 0.278 | 3 | 27 | 10 |

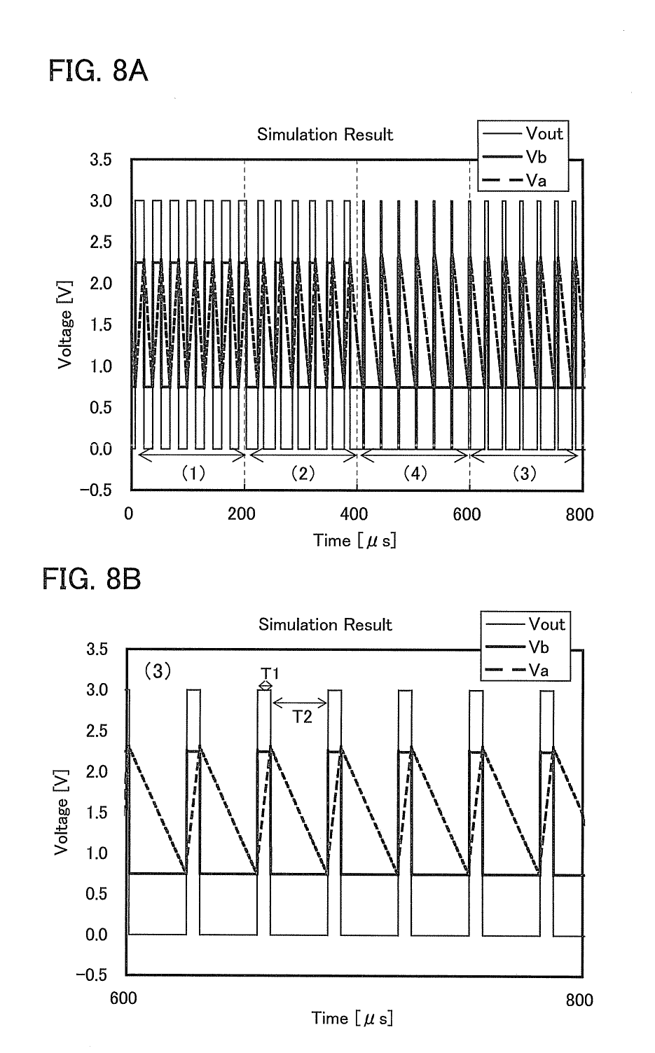

With the use of the oscillator circuit in FIG. 6 and the current supply circuit 102 and the current supply circuit 103 in FIG. 7, calculation was performed on the cases where the signals (an H signal or an L signal) were input as the digital control signals S1 to S7 as shown in (1) to (4) in Table 3. The result of the calculation is shown in FIGS. 8A and 8B.

FIGS. 8A and 8B show the results of output of the output potential Vout of the comparator circuit 101, the potential Va of the one of the input terminals of the comparator circuit 101, and the potential Vb of the other of the input terminals of the comparator circuit 101. FIG. 8A shows calculation results of (1) to (4) in Table 3. FIG. 8B shows a magnification view of the calculation result of (3) in Table 3.

As shown in FIG. 8A, in the cases where signals (an H signal or an L signal) input as the digital control signals S1 to S7 are (1), (2), (4), and (3) in Table 3, the fact that the duty cycles D were approximately 50%, approximately 33%, approximately 10%, and approximately 20%, respectively, was able to be confirmed by the calculation. That is to say, the calculation confirmed that the duty cycle D was able to be changed by the digital control signals S1 to S7 with the use of the oscillator circuit in FIG. 6.

FIG. 8B shows a calculation result in the case of using (3) in Table 3 as signals (an H signal or an L signal) input as the digital control signals S1 to S7. Table 4 shows the current value I1 of the current supply circuit 103, the current value I2 of the current supply circuit 103, the charging period T1, the discharging period T2, and the duty cycle D, which were obtained as a result of the calculation.

TABLE 4

| I1 [μA] | I2 [μA] | T1 [μs] | T2 [μs] | D [%] |
|---|---|---|---|---|
| 1.28 | 0.31 | 5.8 | 25.2 | 18.3 |

By the calculation result in Table 4, the fact that the duty cycle D (18.3%) close to the set duty cycle D (20%) was able to be obtained was able to be confirmed. Note that in the calculation, parasitic capacitance of a transistor and a wiring, parasitic resistance, the current mirroring accuracy a current mirror circuit used for the current supply circuit, and the like were considered. Therefore, the values (set values) in (3) in Table 3 and the values of the calculation result in Table 4 are slightly different.

### EXPLANATION OF REFERENCE

101: comparator circuit; 102: current supply circuit; 103: current supply circuit; 104: switch; 105: switch; 106: capacitor; 107: resistor; 108: resistor; 109: charge and discharge circuit; 111: signal generation circuit; 112: switching circuit; 201: transistor; 202: transistor; 203: transistor; 204: transistor; 205: transistor; 206: transistor; 207: transistor; 208: current supply; 211: transistor; 212: transistor; 213: transistor; 214: transistor; 215: transistor; 216: transistor; 217: transistor; 218: current supply; 301: transistor; 302: transistor; 303: transistor; 304: transistor; 305: transistor; 306: transistor; 307: transistor; 308: transistor; 309: current supply; 401: transistor; 402: transistor; 403: transistor; 404: transistor; 405: transistor; 406: transistor; 407: transistor; 408: transistor; 409: transistor; 410: transistor; 411: transistor; 412: transistor; 413: transistor; 414: current supply; 421: transistor; 422: transistor; 423: transistor; 424: transistor; 425: transistor; 426: transistor; 427: transistor; 428: transistor; 429: transistor; 430: transistor; 431: transistor; 432: transistor; 433: transistor; 434: transistor

This application is based on Japanese Patent Application serial no. 2010-197907 filed with Japan Patent Office on Sep. 3, 2010, the entire contents of which are hereby incorporated by reference.

1. An oscillator circuit comprising:
a comparator circuit;
a capacitor, wherein one of terminals of the capacitor is electrically connected to one of input terminals of the comparator circuit;
a charge and discharge circuit electrically connected to the one of terminals of the capacitor; and
a wiring electrically connected to the other of the input terminals of the comparator circuit, wherein the wiring is supplied with a reference potential,
wherein the charge and discharge circuit comprises:
a first current supply circuit;
a second current supply circuit; and
a switching circuit which is provided between the first current supply circuit and the capacitor and between the second current supply circuit and the capacitor,
wherein an output terminal of the comparator circuit is electrically connected to the switching circuit,
wherein a digital control signal for controlling a current value is supplied to the first current supply circuit and the second current supply circuit.

2. The oscillator circuit according to claim 1,
wherein the switching circuit comprises a first switch provided between the first current supply circuit and the capacitor and a second switch provided between the second current supply circuit and the capacitor, and
wherein each of the first switch and the second switch is turned on or off in accordance with an output potential of the comparator circuit.

3. The oscillator circuit according to claim 1,
wherein the other of the terminals of the capacitor is electrically connected to a wiring supplying any fixed potential.

4. The oscillator circuit according to claim 1, further comprising:
a first resistor provided between an output terminal of the comparator circuit and the other of the input terminals of the comparator circuit; and
a second resistor provided between the other of the input terminals of the comparator circuit and a wiring supplying the reference potential.

5. A semiconductor device comprising the oscillator circuit according to claim 1.

6. A display device comprising a driving circuit, wherein the driving circuit comprises the oscillator circuit according to claim 1.

7. An oscillator circuit comprising:
a comparator circuit configured to compare a potential supplied to one of input terminals with a potential supplied to the other of the input terminals and to output a high power supply potential or a low power supply potential;
a capacitor electrically connected to the one of the input terminals of the comparator circuit;
a charge and discharge circuit configured to charge and discharge the capacitor; and
a wiring supplied with a reference potential and electrically connected to the other of the input terminals of the comparator circuit,
wherein the charge and discharge circuit comprises:
a first current supply circuit configured to generate a current with a first current value;
a second current supply circuit configured to generate a current with a second current value; and
a switching circuit which is provided between the first current supply circuit and the capacitor and between the second current supply circuit and the capacitor,
wherein the switching circuit is configured to connect the capacitor to any one of the first current supply circuit and the second current supply circuit electrically in accordance with an output potential of the comparator circuit,
wherein the first current value and the second current value are controlled with the use of a digital control signal supplied to the first current supply circuit and the second current supply circuit.

8. The oscillator circuit according to claim 7, wherein a duty cycle oh the oscillator circuit is determined in accordance with a ratio the first current value to the second current value.

9. The oscillator circuit according to claim 7,
wherein when the output potential of the comparator circuit becomes the high power supply potential, the switching circuit electrically connects the first current supply circuit and the capacitor and electrically disconnects the second current supply circuit and the capacitor, and
wherein when the output potential of the comparator circuit becomes the low power supply potential, the switching circuit electrically connects the second current supply circuit and the capacitor and electrically disconnects the first current supply circuit and the capacitor.

10. The oscillator circuit according to claim 7, the first current supply circuit is configured to charge the capacitor and the second current supply circuit is configured to discharge the capacitor.

11. The oscillator circuit according to claim 7,
wherein a period for charging the capacitor by the first current supply circuit is determined in accordance with the first current value, and
wherein a period for discharging the capacitor by the second current supply circuit is determined in accordance with the second current value.

12. The oscillator circuit according to claim 7,
wherein one of electrodes of the capacitor is electrically connected to the one of the input terminals of the comparator circuit, and
wherein the other of the terminals of the capacitor is electrically connected to a wiring supplied with any fixed potential.

13. The oscillator circuit according to claim 7,
wherein a potential supplied to the other of the input terminals of the comparator circuit is set in accordance with the output potential of the comparator circuit.

14. The oscillator circuit according to claim 7, further comprising:
a first resistor provided between an output terminal of the comparator circuit and the other of the input terminals of the comparator circuit; and
a second resistor provided between the other of the input terminals of the comparator circuit and a wiring supplied with the reference potential.

15. A semiconductor device comprising the oscillator circuit according to claim 7.

16. A display device comprising a driving circuit, wherein the driving circuit comprises the oscillator circuit according to claim 7.

17. An oscillator circuit comprising:
a comparator circuit configured to compare a potential supplied to one of input terminals with a potential supplied to the other of the input terminals and to output a high power supply potential or a low power supply potential;
a capacitor electrically connected to the one of the input terminals of the comparator circuit;
a charge and discharge circuit configured to charge and discharge the capacitor; and
a wiring supplied with a reference potential and electrically connected to the other of the input terminals of the comparator circuit,
wherein the charge and discharge circuit comprises:
a first current supply circuit configured to generate a current with a first current value;
a second current supply circuit configured to generate a current with a second current value;
a first switch which is provided between the first current supply circuit and the capacitor; and
a second switch which is provided between the second current supply circuit and the capacitor,
wherein an output terminal of the comparator circuit is electrically connected to each of the first switch and the second switch,
wherein the first current value and the second current value are controlled with the use of a digital control signal supplied to the first current supply circuit and the second current supply circuit.

18. The oscillator circuit according to claim 17, wherein a duty cycle oh the oscillator circuit is determined in accordance with a ratio the first current value to the second current value.

19. The oscillator circuit according to claim 17,
wherein when an output potential of the comparator circuit becomes the high power supply potential, the first switch is turned on and the second switch is turned off, and
wherein when the output potential of the comparator circuit becomes the low power supply potential, the second switch is turned on and the first switch is turned off.

20. The oscillator circuit according to claim 17, the first current supply circuit is configured to charge the capacitor and the second current supply circuit is configured to discharge the capacitor.

21. The oscillator circuit according to claim 17,
wherein a period for charging the capacitor by the first current supply circuit is determined in accordance with the first current value, and
wherein a period for discharging the capacitor by the second current supply circuit is determined in accordance with the second current value.

22. The oscillator circuit according to claim 17,
wherein one of electrodes of the capacitor is electrically connected to the one of the input terminals of the comparator circuit, and
wherein the other of the terminals of the capacitor is electrically connected to a wiring supplied with any fixed potential.

23. The oscillator circuit according to claim 17,
wherein a potential supplied to the other of the input terminals of the comparator circuit is set in accordance with an output potential of the comparator circuit.

24. The oscillator circuit according to claim 17, further comprising:
a first resistor provided between an output terminal of the comparator circuit and the other of the input terminals of the comparator circuit; and
a second resistor provided between the other of the input terminals of the comparator circuit and a wiring supplied with the reference potential.

25. A semiconductor device comprising the oscillator circuit according to claim 17.

26. A display device comprising a driving circuit, wherein the driving circuit comprises the oscillator circuit according to claim 17.
